(19) United States
(12) Patent Application Publication
(10) Pub. No.: US 2012/0055541 A1
(43) Pub. Date: Mar. 8, 2012

(54) FRONT-AND-BACK CONTACT SOLAR CELLS, AND METHOD FOR THE PRODUCTION THEREOF

(75) Inventors: Filip Granek, Wroclaw (PL); Daniel Kray, Freiburg (DE); Kuno Mayer, Frankfurt am Main (DE); Monica Aleman, Brussels (DE); Sybille Maria Hopman, Mahlberg (DE)

(73) Assignee: FRAUNHOFER-GESELLSCHAFT zur Forderung der angewandten Forschung e.V., Munich (DE)

(21) Appl. No.: 13/221,106

(22) Filed: Aug. 30, 2011

Related U.S. Application Data
(63) Continuation of application No. PCT/EP2010/000921, filed on Feb. 15, 2010.

(30) Foreign Application Priority Data
Mar. 2, 2009 (DE) 102009011306.1

(51) Int. Cl. H01L 31/02; H01L 31/18

(52) U.S. Cl. 136/252; 438/73; 257/E31.001

(57) ABSTRACT

The invention relates to a method for the production of solar cells which are contacted on both sides, which method is based on micro structuring of a wafer provided with a dielectric layer and doping of the microstructured regions. Subsequently, deposition of a metal-containing nucleation layer and also a galvanic reinforcement of the contactings is effected. The invention relates likewise to solar cells which can be produced in this way.

### PRIORITY INFORMATION

The present application is a continuation of PCT Application No. PCT/EP2010/000921, filed on Feb. 15, 2010, that claims priority to German Application No. 102009011306.1, filed on Mar. 2, 2009, both of which are incorporated herein by reference in their entireties.

### BACKGROUND OF THE INVENTION

The invention relates to a method for the production of solar cells which are contacted on both sides, which method is based on microstructuring of a wafer provided with a dielectric layer and doping of the microstructured regions. Subsequently, deposition of a metal-containing nucleation layer and also a galvanic reinforcement of the contactings is effected. The invention relates likewise to solar cells which can be produced in this way.

The production of solar cells is associated with a large number of process steps for the precision processing of wafers. There are included herein, inter alia, emitter diffusion, application of a dielectric layer and also microstructuring thereof, doping of the wafer, contacting, application of a nucleation layer and also thickening thereof.

With respect to the microstructuring of the front-side contacting, microstructuring of thin silicon nitride layers (SiNₓ) is the common application at present. Such layers currently form the standard antireflection coating in the case of commercial cells. Since this antireflection coating which also serves partially as front-side passivation of the solar cell is applied before the front-side metallisation, this non-conducting layer must be opened locally by corresponding microstructuring, in order to apply the metal contacts directly on the silicon substrate.

The printing of SiNₓ layers with a glass frit-containing metal paste is hereby state of the art. This is firstly dried, the organic solvent being expelled, and then fired at high temperatures (approx. 900° C.). The glass frit thereby attacks the SiNₓ layer, dissolves it locally and consequently enables formation of a silicon-metal contact. The high contact resistance which is produced by the glass fit (>10⁻³ Ωcm²) and the necessary high process temperatures which can reduce both the quality of the passivating layers and also that of the silicon substrate are disadvantageous with this method.

An already known gentle possibility for opening the SiNₓ layer locally resides in the application of photolithography, combined with wet-chemical etching processes. A photoresist layer is thereby firstly applied on the wafer and this is structured via UV exposure and development. There follows a wet-chemical etching step in a hydrofluoric acid-containing or phosphoric acid-containing chemical system which removes the SiNₓ at the places at which the photoresist has been opened. A great disadvantage of this method is the enormous complexity and the costs associated therewith. In addition, a throughput which is adequate for solar cell production cannot be achieved with this method. In the case of some nitrides, the method described here cannot be applied furthermore since the etching rates are too low.

It is known furthermore from the state of the art to remove a passivating layer made of SiNₓ with the help of a laser beam purely by thermal ablation (dry laser ablation).

With respect to doping of the wafers, local doping by photolithographic structuring of an epitaxially grown SiO₂ mask with subsequent whole-surface diffusion in a diffusion furnace is state of the art in microelectronics. The metallisation is achieved by vacuum evaporation on a photolithographically defined resist mask with subsequent solution of the resist in organic solvents. This method has the disadvantage of very great complexity, high time and cost requirement and also whole-surface heating of the component which can change further diffusion layers which are possibly present and also can impair the electronic quality of the substrate.

Local doping can also be effected via screen printing of a self-doping (e.g. aluminium-containing) metal paste with subsequent drying and firing at temperatures around 900° C. The disadvantage of this method is the high mechanical loading of the component, the expensive consumables and also the high temperatures to which the entire component is subjected. Furthermore, merely structural widths >100 μm are herewith possible.

A further method (“buried base contacts”) uses a whole-surface SiNₓ layer, opens this locally by means of laser radiation and then diffuses the doping layer in the diffusion furnace. As a result of the SiNₓ masking, a highly doped zone is formed merely in the laser-opened regions. After back-etching of the resulting phosphorus silicate glass (PSG), the metallisation is formed by currentless deposition in a metal-containing liquid. The disadvantage of this method is the damage introduced by the laser and also the necessary etching step for removing the PSG. In addition, the method consists of several individual steps which make a lot of handling steps necessary.

### SUMMARY OF THE INVENTION

Starting herefrom, it was the object of the present invention to provide a more efficient method for the production of solar cells, in which the number of process steps can be reduced and expensive lithography steps can essentially be dispensed with. Likewise, a reduction in the quantities of metal used for the contacting is intended to be sought.

This object is achieved by the method having the features of claim 1 and the solar cell produced accordingly having the features of claim 18. The further dependent claims reveal advantageous developments.

According to the invention, a method for the production of solar cells which are contacted on both sides is provided, in which
a) a wafer is coated on the front- and the rear-side at least in regions with at least one dielectric layer,
b) microstructuring of the at least one dielectric layer is effected,
c) doping of the microstructured surface regions is effected, by at least one liquid jet which is directed towards the surface of the solid body and comprises at least one doping agent being guided over regions of the surface to be doped, the surface being heated locally in advance or simultaneously by a laser beam,
d) a metal-containing nucleation layer is deposited at least in regions on the rear-side of the wafer and
e) a galvanic deposition, at least in regions, of a metallisation is effected on the front- and the rear-side of the wafer for contacting thereof on both sides.

It is preferred that the microstructuring is effected by treatment of the surface with a dry laser or a water jet-guided laser or a liquid jet-guided laser comprising an etching agent. The use of a liquid jet-guided laser comprising an etching agent is thereby effected such that a liquid jet which is directed towards the surface of the wafer and comprises at least one etching agent for the wafer is guided over regions of the surface to be structured, the surface being heated locally in advance or simultaneously by a laser beam.

A means which has a more strongly etching effect on the at least one dielectric layer than on the substrate is thereby preferably selected as etching agent. The etching agents are particularly preferably selected from the group consisting of H₃PO₄, H₃PO₃, PCl₃, PCl_{S}, POCl₃, KOH, HF/HNO₃, HCl, chlorine compounds, sulphuric acid and mixtures hereof.

The liquid jet can be formed for particular preference from pure or highly concentrated phosphoric acid or even diluted phosphoric acid. The phosphoric acid can be diluted for example in water or in another suitable solvent or used in a different concentration. Also supplements for altering the pH value (acids or alkaline solutions), wetting behaviour (e.g. surfactants) or viscosity (e.g. alcohols) can be added. Particularly good results are achieved when using a liquid which comprises phosphoric acid with a proportion of 50 to 85% by weight. In particular rapid processing of the surface layer can hence be achieved without damaging the substrate and surrounding regions.

Two different things are achieved by the microstructuring according to the invention with very low complexity.

On the one hand, the surface layer in the mentioned regions can be completely removed without the substrate thereby being damaged because the liquid has a less (preferably none) etching effect on the latter. At the same time, due to the local heating of the surface layer in the regions to be removed, as a result of which preferably these regions are heated exclusively, a well-localised removal of the surface layer restricted to these regions is made possible. This results from the fact that the etching effect of the liquid typically increases with increasing temperature so that damage to the surface layer in adjacent, non-heated regions by parts of the etching liquid possibly reaching there is extensively avoided.

The dielectric layer which is deposited on the wafer serves for passivation and/or as antireflection layer. The dielectric layer is preferably selected from the group consisting of SiNₓ, SiO₂, SiOₓ, MgF₂, TiO₂, SiCₓ and Al₂O₃.

It is also possible that a plurality of such layers are deposited one above the other.

Preferably, the doping is implemented in step c) with a liquid jet which comprises H₃PO₄, H₃PO₃ and/or POCl₃ and into which a laser beam is coupled.

The doping agent is preferably selected from the group consisting of phosphorus, boron, aluminium, indium, gallium and mixtures hereof, in particular phosphoric acid, phosphorous acid, solutions of phosphates and hydrogen phosphates, borax, boric acid, borates and perborates, boron compounds, gallium compounds and mixtures thereof.

A further preferred variant provides that the microstructuring and the doping are implemented simultaneously with a liquid jet-guided laser.

A further variant according to the invention comprises doping of the microstructured silicon wafer being effected subsequently to the microstructuring in the case of precision processing and the processing reagent comprising a doping agent.

This can be achieved by using a liquid comprising at least one compound which etches the solid body material instead of the liquid comprising the at least one doping agent. This variant is particularly preferred since, in the same device, firstly the microstructuring and, by means of exchange of liquids, subsequently the doping can be implemented. Alternatively, the microstructuring can also be implemented by means of an aerosol jet, laser radiation not being absolutely necessary in this variant since comparable results can be achieved by preheating the aerosol or the components thereof.

The method according to the invention preferably for microstructuring and doping uses a technical system in which a liquid jet which can be equipped with various chemical systems serves as liquid light guide for a laser beam. The laser beam is coupled into the liquid jet via a special coupling device and is guided by internal total reflection. In this way, a supply of chemicals and laser beam to the process hearth is guaranteed at the same time and location. The laser light thereby assumes various tasks: on the one hand, at the impingement point on the substrate surface it is able to heat the latter locally, optionally thereby to melt it and in the extreme case to vaporise it. As a result of the contemporaneous impingement of chemicals on the heated substrate surface, chemical processes which do not occur under standard conditions because they are kinetically restricted or thermodynamically unfavourable can be activated. In addition to the thermal effect of the laser light, also photochemical activation is possible with respect to the laser light on the surface of the substrate generating for example electron hole pairs which can promote the course of redox reactions in this region or make them possible at all.

In addition to focusing the laser beam and the supply of chemicals, the liquid jet also ensures cooling of the edge regions of the process hearth and rapid transporting away of the reaction products. The last-mentioned aspect is an important prerequisite for conveying and accelerating rapidly occurring chemical (equilibrium) processes. Cooling of the edge regions which are not involved in the reaction and above all are not subjected to the material removal can be protected by the cooling effect of the jet from thermal stresses and crystalline damage resulting therefrom, which enables a low-damage or damage-free structuring of the solar cells. Furthermore, the liquid jet endows the supplied materials, as a result of its high flow speed, with a significant mechanical impetus which is particularly effective when the jet impinges on a molten substrate surface.

Laser beam and liquid jet together form a new process tool which is in principle superior in its combination to the individual systems which it comprises.

The metal-containing nucleation layer is preferably deposited by vacuum evaporation, sputtering or by reduction from aqueous solution. This is effected preferably simultaneously on the front- and the rear-side of the wafer. The metal-containing nucleation layer thereby preferably comprises a metal from the group aluminium, nickel, titanium, chromium, tungsten, silver and alloys thereof.

After application of the nucleation layer, this is preferably treated thermally, e.g. by laser annealing.

After deposition of the metal-containing nucleation layer, a layer is preferably deposited at least in regions on the front-side of the wafer in order to increase adhesion.

This layer for increasing adhesion preferably comprises a metal selected from the group consisting of nickel, titanium, copper, tungsten and alloys hereof or consists of these metals.

After application of the metal-containing nucleation layer, preferably thickening of the nucleation layer, at least in regions, is effected by galvanic deposition of a metallisation, in particular of silver or copper, as a result of which contacting of the front- and of the rear-side of the wafer is effected.

Preferably, as laminar a liquid jet as possible is used for implementation of the method. The laser beam can be guided then particularly effectively by total reflection in the liquid jet so that the latter fulfils the function of a light guide. Coupling of the laser beam can be effected in a nozzle unit, for example through a window which is orientated perpendicular to a beam direction of the liquid jet. The window can thereby be configured also as a lens for focusing the laser beam. Alternatively or additionally, also a lens which is independent of the window can be used for focusing or forming the laser beam. The nozzle unit can thereby be designed in a particularly simple embodiment of the invention such that the liquid is supplied from one side or from a plurality of sides in the direction radial to the beam direction.

There are preferred as usable types of laser:

Various solid body lasers, in particular the commercially frequently used Nd—YAG laser of wavelength 1,064 nm, 532 nm, 355 nm, 266 nm and 213 nm, diode lasers with wavelengths <1,000 nm, argon-ion lasers of wavelength 514 to 458 nm and excimer lasers (wavelengths: 157 to 351 nm).

The quality of the microstructuring tends to increase with reducing wavelength because the energy induced by the laser in the surface layer is thereby increasingly concentrated better and better on the surface, which tends to lead to reducing the heat influence zone and, associated therewith, to reducing the crystalline damage in the material, above all in the phosphorus-doped silicon below the passivating layer.

In this context, blue lasers and lasers in the near UV range (e.g. 355 nm) with pulse lengths in the femtosecond to nanosecond range prove to be particularly effective. By using in particular short-wave laser light, the option of direct generation of electrons/hole pairs in silicon which can be used for the electrochemical process during the nickel deposition (photochemical activation) exists in addition. Thus, free electrons in the silicon generated for example by laser light can contribute, in addition to the redox process of nickel ions with phosphorous acid, which was already described above, directly to the reduction of nickel on the surface. This electron/hole generation can be permanently maintained by permanent illumination of the sample at defined wavelengths (in particular in the near UV with λ≦355 nm) during the structuring process and can promote the metal nucleation process in a lasting manner.

For this purpose, the solar cell property can be used in order to separate the excess charge carriers via the p-n junction and hence to charge the n-conducting surface negatively.

A further preferred variant of the method according to the invention provides that the laser beam is adjusted actively in temporal and/or spatial pulse form. There are included herein the flat top form, an M-profile or a rectangular pulse.

According to the invention, a solar cell which is producible according to the previously described method is likewise provided.

The subject according to the invention is intended to be explained in more detail with reference to the subsequent FIGURE and the subsequent example without wishing to restrict said subject to the special embodiments shown here.

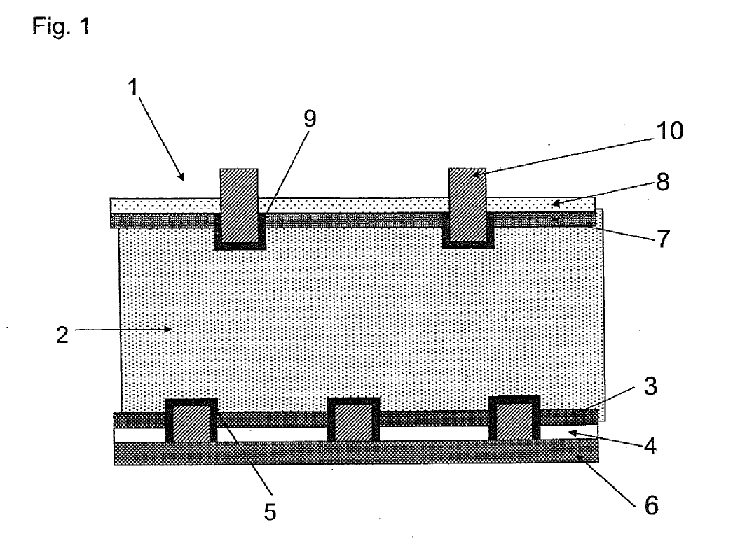

FIG. 1 shows an embodiment of the solar cell produced according to the invention.

### DETAILED DESCRIPTION OF THE ILLUSTRATED EMBODIMENT

The solar cell 1 according to the invention in FIG. 1 has a wafer on an Si basis 2 which is coated on the rear-side with a flat, whole-surface emitter 3. A passivating layer 4 is disposed on the emitter layer. In defined regions, an electrical field on the rear-side 5 (back surface field) and a rear-side contact 6 is illustrated here. On the front-side of the wafer 2, a flat, whole-surface emitter 7 and also a passivating layer 8 is disposed. In the surface regions, regions with a highly doped emitter (n⁺) 9 and front-side contacts 10 are disposed at defined places.

### Example 1

A sawn p-type wafer is firstly subjected to a damage etch in order to remove the wire saw damage, this damage etch being implemented in 40% KOH at 80° C. for 20 minutes. There follows texturing of the wafer on one side in 1% KOH at 98° C. (duration approx. 35 minutes). In a subsequent step, a light emitter diffusion is effected in the tubular furnace with phosphoryl chloride (POCl₃) as phosphorus source. The layer resistance of the emitter is in a range of 100 to 400 ohm/sq. Subsequently, a thin thermal oxide layer is produced in the tubular furnace by flowing water vapour thereover. The thickness of the oxide layer is hereby in a range of 6 to 15 nm. In the following process step, a PECVD deposition of silicon nitride is effected (refractive index n=2.0 to 2.1, thickness of the layer: approx. 60 nm) on the front-side and a silicon dioxide layer (thickness: approx. 200 nm) on the rear-side. The thus treated wafer is subsequently structured with the liquid jet. Cutting and simultaneous doping of the channel walls is hereby effected with the help of a laser which is coupled to a liquid jet (so-called laser chemical processing, LCP). 85% phosphoric acid is used as jet medium. The line width of the structures is approx. 30 μm and the spacing between 2 lines 1 to 2 mm. An Nd:YAG laser at 532 nm (P=7 W) is thereby used. The travel speed is 400 mm/s. The thus structured and doped wafer is subsequently subjected to a currentless deposition of nickel with the help of the LCP process. An aqueous solution with NiSO₄ (c=3 mol/l) and H₃PO₃ (c=3 mol/l) is used here as jet medium. Laser parameters and travel speed are identical to the previous method step. Subsequently, the formation of a local back-surface-field (BSF) is effected by means of LCP, for which boric acid (c=40 g/l) is used. The line width is approx. 30 μm and the spacing between the lines 200 μm to 2 mm. Here also, laser parameters and travel speed are identical to the two previous method steps. Subsequently, vapour evaporation of aluminium on the rear-side (thickness: approx. 50 nm) is effected and the subsequent vacuum evaporation of the contact metal is effected on the rear-side (e.g. titanium, thickness: approx. 30 nm). Subsequently, sintering of the front-side and rear-side contacts is optionally effected at temperatures of 300 to 500° C. in a forming gas atmosphere (N₂H₂). Finally, a light-induced deposition of silver or copper is effected in order to thicken the front- and rear-side contacts up to a thickness of the contacts of approx. 10 μm. For the galvanic bath, silver cyanide (c=1 mol/l) is used here as silver source. The bath temperature is 25° C., the voltage applied to the wafer rear-side 0.3 V. A halogen lamp with a wavelength of 253 nm is used for the light induction.

What is claimed is:

1. A method for the production of solar cells which are contacted on both sides, in which
a) a wafer is coated on the front- and the rear-side at least in regions with at least one dielectric layer,
b) microstructuring of the at least one dielectric layer is effected,
c) doping of the microstructured surface regions is effected, by at least one liquid jet which is directed towards the surface of the solid body and comprises at least one doping agent being guided over regions of the surface to be doped, the surface being heated locally in advance or simultaneously by a laser beam,
d) a metal-containing nucleation layer is deposited at least in regions on the rear-side of the wafer and
e) a galvanic deposition, at least in regions, of a metallisation is effected on the front- and the rear-side of the wafer for contacting thereof on both sides.

2. The method according to claim 1,
wherein the microstructuring is effected by treatment of the surface with a dry laser or a water jet-guided laser or a liquid jet-guided laser comprising an etching agent, by a liquid jet which is directed towards the surface of the solid body and comprises at least one etching agent for the wafer being guided over regions of the surface to be structured, the surface being heated locally in advance or simultaneously by a laser beam.

3. The method according to claim 1, wherein the etching agent has a more strongly etching effect on the at least one dielectric layer than on the substrate and is selected in particular from the group consisting of H₃PO₄, H₃PO₃, PCl₃, PCl₅, POCl₃, KOH, HF/HNO₃, HCl, chlorine compounds, sulphuric acid and mixtures hereof.

4. The method according to claim 1, wherein the dielectric layer is selected from the group consisting of SiNₓ, SiO₂, SiOₓ, MgF₂, TiO₂, SiCₓ and Al₂O₃.

5. The method according to claim 1, wherein the doping is implemented with a liquid jet which comprises H₃PO₄, H₃PO₃ and/or POCl₃ and into which a laser beam is coupled.

6. The method according to claim 1, wherein the at least one doping agent is selected from the group consisting of phosphorus, boron, aluminium, indium, gallium and mixtures hereof, in particular phosphoric acid, phosphorous acid, solutions of phosphates and hydrogen phosphates, borax, boric acid, borates and perborates, boron compounds, gallium compounds and mixtures thereof.

7. The method according to claim 1, wherein the microstructuring and the doping are implemented simultaneously with a liquid jet-guided laser.

8. The method according to claim 1, wherein the metal-containing nucleation layer is deposited by vapour deposition, sputtering or by reduction from aqueous solution, preferably simultaneously on the front- and the rear-side of the wafer.

9. The method according to claim 1, wherein the metal-containing nucleation layer comprises a metal from the group aluminium, nickel, titanium, chromium, tungsten, silver and alloys thereof.

10. The method according to claim 1, wherein, after application of the nucleation layer, this is treated thermally, in particular by laser annealing.

11. The method according to claim 1, wherein, after deposition of the metal-containing nucleation layer on the front-side, a layer is deposited at least in regions in order to increase adhesion.

12. The method according to claim 11, wherein the layer for increasing adhesion comprises a metal selected from the group consisting of nickel, titanium, copper, tungsten and alloys hereof or consists of the latter.

13. The method according to claim 1, wherein, after application of the metal-containing nucleation layer, thickening of the nucleation layer, at least in regions, is effected by galvanic deposition of a metallisation, in particular of silver or copper, as a result of which contacting of the front- and of the rear-side of the wafer is effected.

14. The method according to claim 1, wherein the laser beam is guided by total reflection in the liquid jet.

15. The method according to claim 1, wherein the liquid jet is laminar.

16. The method according to claim 1, wherein the liquid jet has a diameter of 10 to 500 μm.

17. The method according to claim 1, wherein the laser beam is adjusted actively in temporal and/or spatial pulse form, in particular flat top form, M-profile or rectangular pulse.

18. A solar cell producible according to the method of claim 1.
